(19) United States
(12) Patent Application Publication
(10) Pub. No.: US 2026/0096127 A1
(43) Pub. Date: Apr. 2, 2026

(54) NITRIDE-BASED SEMICONDUCTOR DEVICE AND METHOD FOR MANUFACTURING THEREOF

(71) Applicant: INNOSCIENCE (SUZHOU) SEMICONDUCTOR CO., LTD., Suzhou, Jiangsu (CN)

(72) Inventors: Jian RAO, Suzhou, Jiangsu (CN); Junhui MA, Suzhou, Jiangsu (CN); Yulong ZHANG, Suzhou, Jiangsu (CN); Jheng-Sheng YOU, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/111,019

(22) PCT Filed: Sep. 16, 2022
(86) PCT No.: PCT/CN2022/119243

§ 371 Date: Mar. 12, 2025

(51) Int. Cl. H10D 30/47; H01L 23/522; H01L 23/528; H10D 30/01; H10D 62/824; H10D 64/00

(52) U.S. Cl. CPC H10D 30/475; H10D 30/015; H10D 62/824; H10D 64/112; H10W 20/42; H10W 20/435

(57) ABSTRACT

The nitride-based semiconductor device includes a first nitride-based semiconductor layer, a second nitride-based semiconductor layer, a gate electrode, an ohmic electrode, a first field plate, and a second field plate. The second nitride-based semiconductor layer is disposed on the first nitride-based semiconductor layer. The gate electrode is disposed above the second nitride-based semiconductor layer. The ohmic electrode is disposed above the second nitride-based semiconductor layer. The first field plate is disposed above the second nitride-based semiconductor layer and between the gate electrode and the ohmic electrode. The second field plate is disposed above the first field plate and vertically overlapping with the first field plate. The second field plate has at least one portion extending downward to make contact with at least one connection region of the first field plate, and an isolation region of the first field plate is wrapped by dielectric.

### CROSS-REFERENCE TO RELATED APPLICATIONS

This application is a national stage of international PCT application No. PCT/CN2022/119243 filed on Sep. 16, 2022, the entire contents of which are incorporated herein by reference.

### FIELD

The present disclosure generally relates to a nitride-based semiconductor device. More specifically, the present disclosure relates to a nitride-based semiconductor device having field plates connected to each other directly.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY

In accordance with one aspect of the present disclosure, a nitride-based semiconductor device is provided. The nitride-based semiconductor device includes a first nitride-based semiconductor layer, a second nitride-based semiconductor layer, a gate electrode, an ohmic electrode, a first field plate, and a second field plate. The second nitride-based semiconductor layer is disposed on the first nitride-based semiconductor layer and has a bandgap greater than a bandgap of the first nitride-based semiconductor layer. The gate electrode is disposed above the second nitride-based semiconductor layer. The ohmic electrode is disposed above the second nitride-based semiconductor layer. The first field plate is disposed above the second nitride-based semiconductor layer and between the gate electrode and the ohmic electrode. The second field plate is disposed above the first field plate and vertically overlapping with the first field plate. The second field plate has at least one portion extending downward to make contact with at least one connection region of the first field plate, and an isolation region of the first field plate is wrapped by dielectric.

In accordance with one aspect of the present disclosure, a method for manufacturing a nitride-based semiconductor device is provided. The method has steps as follows. A first nitride-based semiconductor layer is formed. A second nitride-based semiconductor layer is formed on the first nitride-based semiconductor layer. A gate electrode is formed over the second nitride-based semiconductor layer. An ohmic electrode is formed over the second nitride-based semiconductor layer. The first field plate is formed above the second nitride-based semiconductor layer and between the gate electrode and the ohmic electrode. A second field plate is formed above the first field plate. The second field plate vertically overlaps with the first field plate, in which the second field plate has at least one portion extending downward to make contact with at least one connection region of the first field plate.

In accordance with one aspect of the present disclosure, a nitride-based semiconductor device is provided. The nitride-based semiconductor device includes a first nitride-based semiconductor layer, a second nitride-based semiconductor layer, a gate electrode, an ohmic electrode, a first field plate, and a second field plate. The second nitride-based semiconductor layer is disposed on the first nitride-based semiconductor layer and has a bandgap greater than a bandgap of the first nitride-based semiconductor layer. The gate electrode is disposed above the second nitride-based semiconductor layer. The ohmic electrode is disposed above the second nitride-based semiconductor layer. The first field plate is disposed above the second nitride-based semiconductor layer and between the gate electrode and the ohmic electrode, in which the first field plate is composed of a connection region and an isolation region. The second field plate is disposed above the first field plate and has at least one portion extending downward to make contact with the connection region of the first field plate.

By the above configuration, the manufacturing process of the semiconductor device is simplified. In this regard, an extra conductive pillar may penetrate a field plate during formation. Therefore, the configuration of two field plates directly connected to each other can improve reliability and yield rate of devices.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a nitride-based semiconductor device according to some embodiments of the present disclosure;

FIG. 1B is a side view of the nitride-based semiconductor device according to some embodiments of the present disclosure;

FIG. 2A, FIG. 2B, FIG. 2C, FIG. 2D, and FIG. 2E show different stages of a method for manufacturing a nitride-based semiconductor device according to some embodiments of the present disclosure;

FIG. 3 is a side view of the nitride-based semiconductor device according to some embodiments of the present disclosure;

FIG. 4 is a vertical cross-sectional view of a nitride-based semiconductor device according to some embodiments of the present disclosure; and

FIG. 5 is a vertical cross-sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

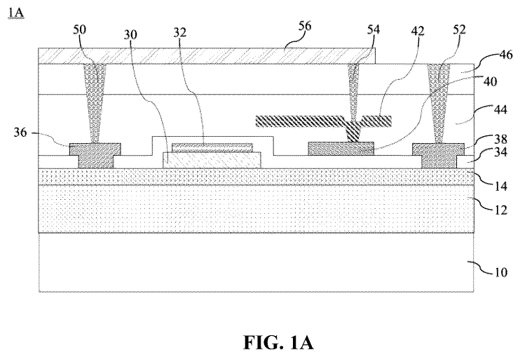

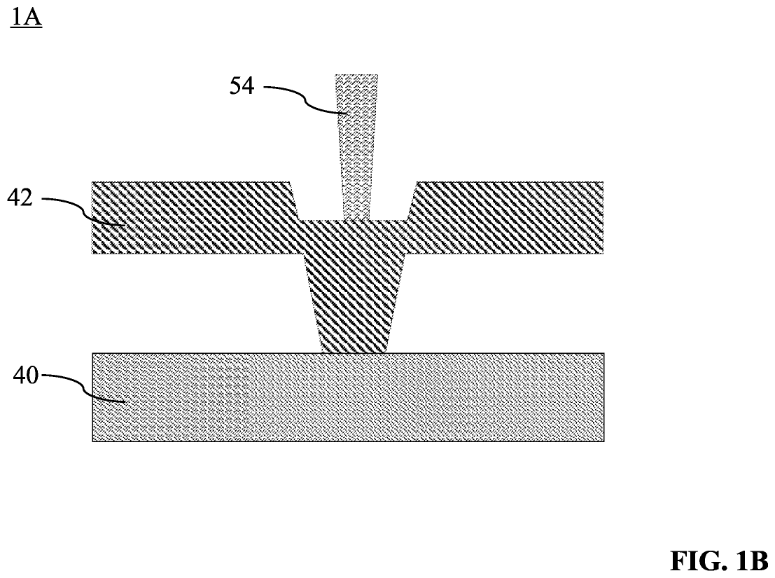

FIG. 1A is a vertical cross-sectional view of a nitride-based semiconductor device 1A according to some embodiments of the present disclosure. The nitride-based semiconductor device 1A includes a substrate 10, nitride-based semiconductor layers 12, 14, a doped nitride-based semiconductor layer 30, a gate electrode 32, a passivation layer 34, electrodes 36 and 38, filed plates 40 and 42, passivation layers 44 and 46, contact vias 50, 52, 54, and a patterned conductive layer 56.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

In some embodiments, the nitride-based semiconductor device 1A may further include a buffer layer (not illustrated). The buffer layer is disposed between the substrate 10 and the nitride-based semiconductor layer 12. The buffer layer can be configured to reduce lattice and thermal mismatches between the substrate 10 and the nitride-based semiconductor layer 12, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and a buffer layer. The nucleation layer can be configured to provide a transition to accommodate a mismatch/difference between the substrate 10 and a III-nitride layer of the buffer layer. The exemplary material of the nucleation layer can include, for example but is not limited to AIN or any of its alloys.

The nitride-based semiconductor layer 12 can be disposed on/over/above the buffer layer. The nitride-based semiconductor layer 14 can be disposed on/over/above the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, AlₓGa₍₁₋ₓ₎N where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 12 and 14 are selected such that the nitride-based semiconductor layer 14 has a bandgap (i.e., forbidden band width) greater/higher than a bandgap of the nitride-based semiconductor layer 12, which causes electron affinities thereof different from each other and forms a heterojunction therebetween. For example, when the nitride-based semiconductor layer 12 is an undoped GaN layer having a bandgap of approximately 3.4 eV, the nitride-based semiconductor layer 14 can be selected as an AlGaN layer having bandgap of approximately 4.0 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The electrodes 36 and 38 are disposed on the nitride-based semiconductor layer 14. The electrode 36 can make contact with the nitride-based semiconductor layer 14. The electrode 38 can make contact with the nitride-based semiconductor layer 14. Each of the electrodes 36 and 38 can serve as a source electrode or a drain electrode. In some embodiments, the electrodes 36 and 38 can be called ohmic electrodes.

In some embodiments, the electrodes 36 and 38 can include, for example but are not limited to, metals, alloys, doped semiconductor materials (such as doped crystalline silicon), compounds such as silicides and nitrides, other conductor materials, or combinations thereof. The exemplary materials of the electrodes 36 and 38 can include, for example but are not limited to, Ti, AlSi, TiN, or combinations thereof. The electrodes 36 and 38 may be a single layer, or plural layers of the same or different composition. In some embodiments, the electrodes 36 and 38 can form ohmic contact with the nitride-based semiconductor layer 14. The ohmic contact can be achieved by applying Ti, Al, or other suitable materials to the electrodes 36 and 38.

In some embodiments, each of the electrodes 36 and 38 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped nitride-based semiconductor layer 30 is disposed over the nitride-based semiconductor layer 14. The doped nitride-based semiconductor layer 30 is located between the electrodes 36 and 38. The doped nitride-based semiconductor layer 30 may be p-type. The doped nitride-based semiconductor layer 30 is configured to bring the device into enhancement mode. The doped nitride-based semiconductor layer 30 can be a p-type doped III-V semiconductor layer.

The exemplary materials of the doped nitride-based semiconductor layer 30 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg.

The gate electrode 32 is disposed on the doped nitride-based semiconductor layer 30. The exemplary materials of the electrode 32 may include metals or metal compounds. The electrode 32 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds. In some embodiments, the gate electrode 32 is formed by patterning the same conductive layer and thus the gate electrode 32 have the same material.

The passivation layer 34 is disposed over the nitride-based semiconductor layer 14. The passivation layer 34 can cover the doped nitride-based semiconductor layer 30 and the gate electrode 32. The passivation layer 34 can be formed by protection purpose with respect to the doped nitride-based semiconductor layer 30 and the gate electrode 32 so the passivation layer 34 can be called a protection layer as well. The electrodes 36 and 38 can penetrate the passivation layer 34. The material of the passivation layer 34 can include, for example but are not limited to, dielectric materials. For example, the passivation layer 34 can include SiNₓ, SiOₓ, SiON, SiC, SiBN, SiCBN, oxides, nitrides, plasma enhanced oxide (PEOX), or combinations thereof.

The field plate 40 is disposed above the nitride-based semiconductor layer 14 and the passivation layer 34. The field plate 40 is disposed between the gate electrode 32 and the electrode 38. The exemplary material of the field plate 40 can include, for example but are not limited to, conductive materials, such as Ti, Ta, TiN, TaN, or combinations thereof. In some embodiments, other conductive materials such as Al, Cu, doped Si, and alloys including these materials may also be used.

The field plate 42 is disposed above the field plate 40. The field plate 42 is disposed between the gate electrode 32 and the electrode 38. The field plate 42 vertically overlaps with the field plate 40. The field plate 42 is parallel with the field plate 40. The field plate 42 has at least one portion extending downward to make contact with at least one connection region of the field plate 40. The field plate 42 includes a recessed portion directly above the connection region of the field plate 40. The location of the recessed portion of the field plate 42 is defined by the portion extending downward to make contact with the connection region of the field plate 40. The exemplary material of the field plate 42 can include, for example but are not limited to, conductive materials, such as Ti, Ta, TiN, TaN, or combinations thereof. In some embodiments, other conductive materials such as Al, Cu, doped Si, and alloys including these materials may also be used.

The passivation layer 44 is disposed over the passivation layer 34. The passivation layer 44 can cover the field plates 40 and 42. The passivation layer 44 can have at least one portion serving as a dielectric layer which is at least disposed between the field plates 40 and 42. The dielectric layer of the passivation layer 44 can enclose the extending-downward portion of the field plate 42. In some embodiments, the passivation layer 44 can serve as a planarization layer which has a level top surface to support other layers/elements. In some embodiments, the passivation layer 44 can be formed as a thicker layer, and a planarization process, such as chemical mechanical polish (CMP) process, is performed on the passivation layer 44 to remove the excess portions, thereby forming a level top surface. The material of the passivation layer 44 can include, for example but are not limited to, dielectric materials. For example, the passivation layer 44 can include SiNₓ, SiOₓ, SiON, SiC, SiBN, SiCBN, oxides, nitrides, plasma enhanced oxide (PEOX), or combinations thereof.

In addition of the connection region, the field plate 40 further has an isolation region wrapped by dielectric of the passivation layer 44. The passivation layer 44 can have at least one portion serving as a dielectric layer entirely wrapping the isolation region of the field plate 40. In some embodiments, an outer surface of the field plate 40 is composed of the connection region and the isolation region. That is, the connection region of the field plate 40 is the only interface of the externally electrical path for the field plate 40. With respect to areas, the connection region is smaller than the isolation region.

More specifically, the field plate 42 is the only one that electrically connects with the field plate 40. The field plate 42 can be configured to modulate electrical field plate distribution and directly connect to the field plate 40. There is no need to form any extra conductive pillar between the field plates 40 and 42. As such, the manufacturing process of the semiconductor device 1A is simplified. In the configuration with an extra conductive pillar, the extra conductive pillar may penetrate the field plate 40 during the formation. Furthermore, at a configuration that two field plates are connected to two conductive pillars respectively, a slightly electric potential difference may be generated between the two field plates and thus the electrical uniformity is reduced. Moreover, the two conductive pillars may cause parasitic currents for each other.

The passivation layer 46 is disposed over the passivation layer 44. The passivation layer 46 can cover the passivation layer 44. In some embodiments, the passivation layer 46 can serve as a planarization layer which has a level top surface to support other layers/elements. The material of the passivation layer 46 can include, for example but are not limited to, dielectric materials. For example, the passivation layer 46 can include SiNₓ, SiOₓ, SiON, SiC, SiBN, SiCBN, oxides, nitrides, plasma enhanced oxide (PEOX), or combinations thereof.

The contact vias 50 and 52 are disposed within the passivation layers 44 and 46. The contact vias 50 and 52 can penetrate the passivation layers 44 and 46. The contact vias 50 and 52 can extend longitudinally to connect to the electrodes 36 and 38. In some embodiments, the semiconductor device 1A further includes a contact via extending longitudinally to connect to the gate electrode 32. The upper surfaces of the contact vias 50 and 52 are free from coverage of the passivation layer 46. The exemplary materials of the contact vias 50 and 52 can include, for example but are not limited to, conductive materials, such as metals or alloys.

FIG. 1B is a side view of the nitride-based semiconductor device 1A according to some embodiments of the present disclosure. The “side view” includes viewing the nitride-based semiconductor device 1A of FIG. 1A by the right side. The relationship among the field plates 40 and 42 and the contact via 54 is illustrated in FIG. 1B. As shown in FIGS. 1A and 1B, the contact via 54 is disposed over the field plates 40 and 42. The contact via 54 extends vertically to make contact with the field plate 42. The contact via 54 is directly connected to the recessed portion of the field plate 42. The contact via 54 aligns with the extending-downward portion of the field plate 42. Even though the formation of the contact via 54 may over etch the field plate 42, the extending-downward portion of the field plate 42 can have enough thickness to avoid breaking of the field plate 42.

The patterned conductive layer 56 is disposed on/over/above the passivation layer 46 and the contact vias 50 and 54. The patterned conductive layer 56 is in contact with the contact vias 50 and 54. The contact vias 50 and 54 can have the same electric potential through the patterned conductive layer 56. Therefore, the field plates 40 and 42 can be called source field plates as well. The patterned conductive layer 56 may have metal lines, pads, traces, or combinations thereof, such that the patterned conductive layer 56 can form at least one circuit. Hence, the patterned conductive layer 56 can be served as a patterned circuit layer. An external electronic device can send at least one electronic signal to the semiconductor device 1A by the patterned conductive layer 56. The exemplary materials of the patterned conductive layer 56 can include, for example but are not limited to, conductive materials. The patterned conductive layer 56 may include a single film or multilayered film having Ag, Al, Cu, Mo, Ni, Ti, alloys thereof, oxides thereof, nitrides thereof, or combinations thereof.

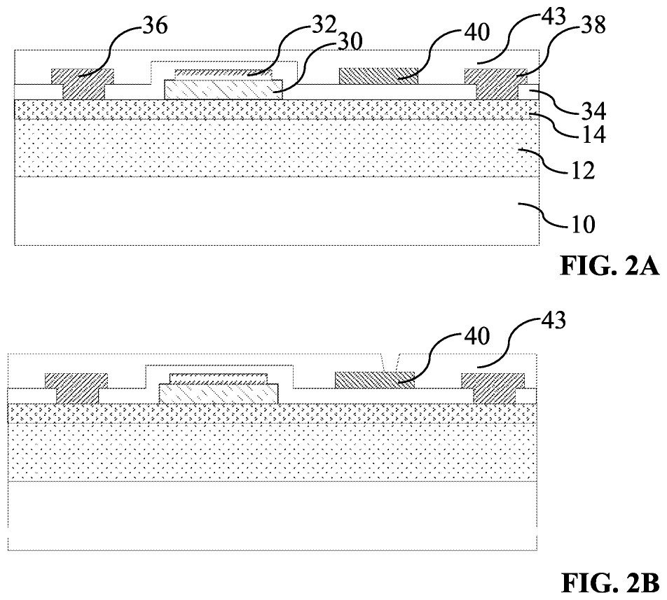

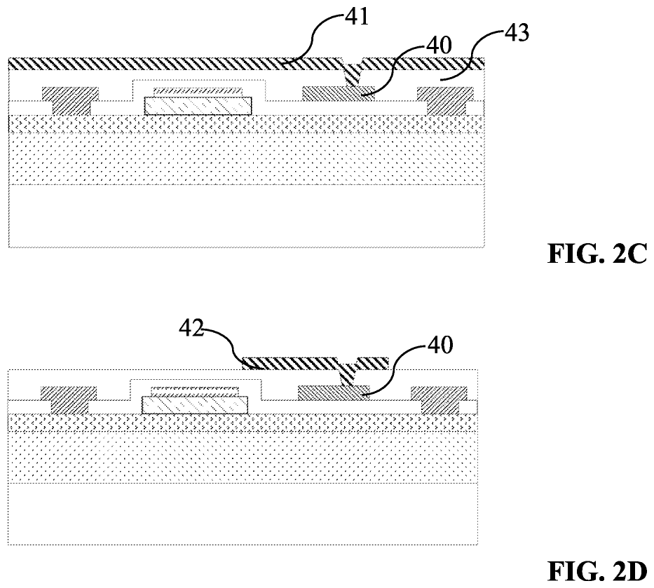

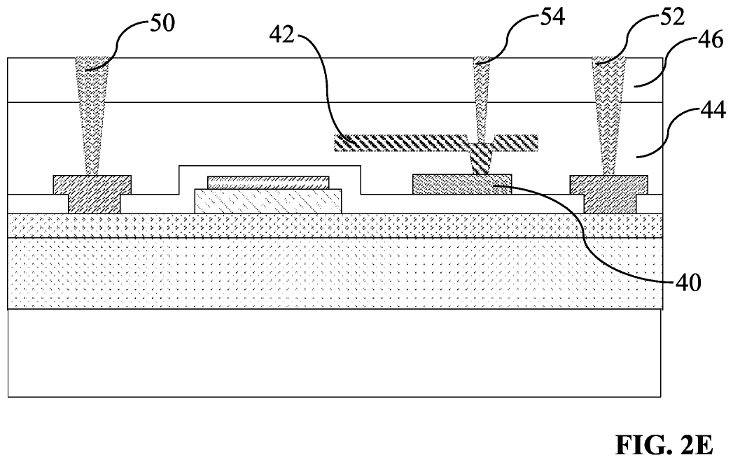

Different stages of a method for manufacturing the semiconductor device 1A are shown in FIG. 2A, FIG. 2B, FIG. 2C, FIG. 2D, and FIG. 2E, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 10 is provided. A nitride-based semiconductor layer 12 is formed on the substrate 10. A nitride-based semiconductor layer 14 is formed on the nitride-based semiconductor layer 12. A doped nitride-based semiconductor layer 30 is formed on/over/above the nitride-based semiconductor layer 14. A gate electrode 32 is formed over the doped nitride-based semiconductor layer 30. A passivation layer 34 is formed on/over/above the nitride-based semiconductor layer 14 to cover the doped nitride-based semiconductor layer 30 and the gate electrode 32. Electrodes 36 and 38 are formed to penetrate the passivation layer 34 and make contact with the nitride-based semiconductor layer 14. A field plate 40 is disposed over the passivation layer 34. A passivation layer 43 is formed over the passivation 34 to cover the electrodes 36 and 36 and the field plate 40. After the formation of the passivation layer 43, an isolation region of the field plate 40 is wrapper by a dielectric layer of the passivation layer 43.

Referring to FIG. 2B, an opening is formed within the passivation layer 43 so a portion of the field plate 40 is exposed. The exposed portion of the field plate 40 can serve as a connection region so the field plate 40 is composed of the isolation region and the connection region.

Referring to FIG. 2C, a blanket conductive layer 41 is formed over the passivation layer 43. The blanket conductive layer 41 can extend into the opening of the passivation layer 43 so can make contact with the connection region of the field plate 40.

Referring to FIG. 2D, the blanket conductive layer 41 is patterned such that a field plate 42 directly connecting to the field plate 40 is formed. The field plate 42 can be formed to have a width greater than a width of the field plate 40.

Referring to FIG. 2E, passivation layers 44 and 46, contact vias 50, 52, 54 are formed over the structure. In some embodiments, the contact via 54 is in contact with the field plate 42 such that the contact via 54 is electrically coupled with the field plate 40 via the field plate 42. Then, a patterned conductive layer 56 is formed over the structure.

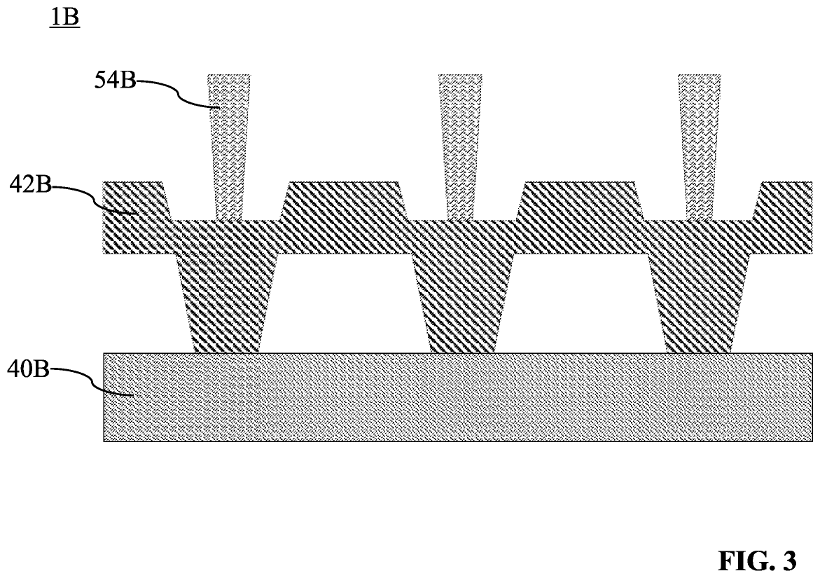

FIG. 3 is a side view of a nitride-based semiconductor device 1B according to some embodiments of the present disclosure. The viewing angle of FIG. 3 is identical with that of FIG. 1B. The nitride-based semiconductor device 1B is similar to the semiconductor device 1A as described and illustrated with reference to FIGS. 1A and 1B, except that the field plates 40, 42 and the contact via 54 of the semiconductor device 1A are replaced by that field plates 40B, 42B and contact vias 54B.

In the present embodiment, the field plate 42B has a plurality of portions extending downward to make contact with connection regions of the field plate 40B. The field plate 40B is composed of multiple connection region and one isolation region, in which the connection regions of the field plate 40B are arranged along a direction (e.g., a lateral direction). In some embodiments, the connection regions are arranged to have a fixed spacing between any two of the adjacent connection regions. The configuration that the multiple extending-downward portions of the field plate 42B make contact with the multiple connection regions of the field plates 40B respectively can improve the reliability of the connection. For example, once one of the extending-downward portions fails to get contact, others of the extending-downward portions can keep electrical connection.

Correspondingly, the multiple contact vias 54B are disposed over the field plate 42B and extend vertically to make contact with the field plate 42B. All of the contact vias 54B are arranged along a direction (e.g., a lateral direction) to form an array. The configuration that the multiple contact vias 54B make contact with the field plate 42B can improve the reliability of the connection. For example, once one of the contact vias 54B fails to get connection, others of the contact vias 54B can keep electrical connection.

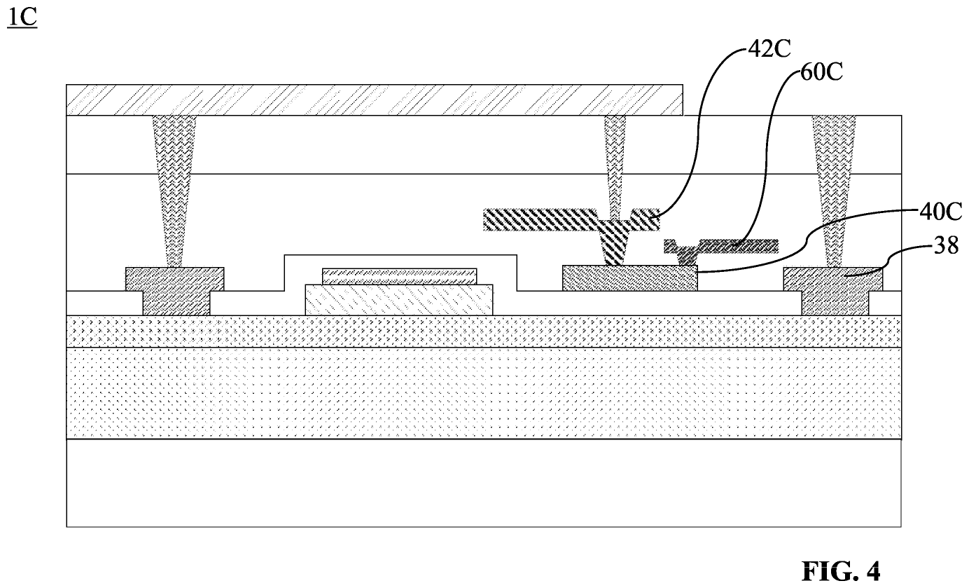

FIG. 4 is a vertical cross-sectional view of a nitride-based semiconductor device 1C according to some embodiments of the present disclosure. The nitride-based semiconductor device 1C is similar to the semiconductor device 1A as described and illustrated with reference to FIGS. 1A and 1B, except that the field plates 40, 42 and the contact via of the semiconductor device 1A are replaced by the field plates 40C, 42C. The nitride-based semiconductor device 1C further includes a field plate 60C.

In the present embodiment, the field plate 60C is disposed between the field plates 40C and 42C. The field plate 60C is at a position higher than the field plate 40C and lower than the field plate 42C. The field plate 60C has at least one portion extending downward to make contact with the field plate 40C. The field plate 60C can extend to get close the electrode 38. The field plate 60C is closest to the electrode 38 among the first field plate, the second field plate, and the third field plate. By such the configuration, although the field plate number increases, no extra conductive pillar is needed such that the manufacturing process can get simplified.

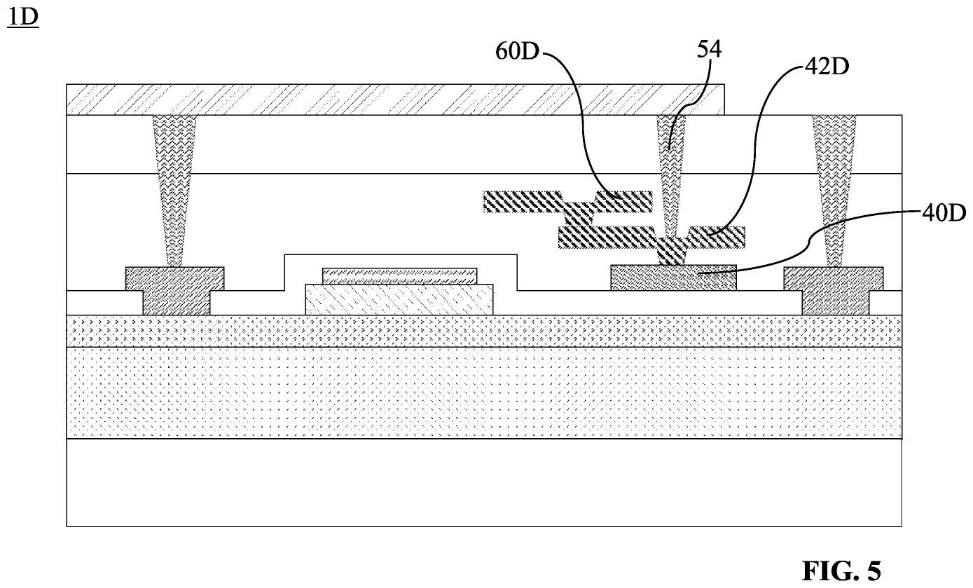

FIG. 5 is a vertical cross-sectional view of a nitride-based semiconductor device 1D according to some embodiments of the present disclosure. The nitride-based semiconductor device 1D is similar to the semiconductor device 1A as described and illustrated with reference to FIGS. 1A and 1B, except that the field plates 40, 42 and the contact via of the semiconductor device 1A are replaced by that field plates 40D, 42D. The nitride-based semiconductor device 1C further includes a field plate 60D.

In the present embodiment, the field plate 60D is disposed over the field plates 40D and 42D. The field plate 60D has at least one portion extending downward to make contact with the field plate 42D. The field plate 60D can extend to get away from the contact via 54. The field plate 60D can extend to over the left-most edge of the field plate 42D. The field plate 42D is the only component that the field plate 60D can get electrically coupled with the contact via 54. By such the configuration, although the field plate number increases, no extra conductive pillar is needed such that the manufacturing process can get simplified.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer;
a gate electrode disposed above the second nitride-based semiconductor layer;
an ohmic electrode disposed above the second nitride-based semiconductor layer;
a first field plate disposed above the second nitride-based semiconductor layer and between the gate electrode and the ohmic electrode; and
a second field plate disposed above the first field plate and vertically overlapping with the first field plate, wherein the second field plate has at least one portion extending downward to make contact with at least one connection region of the first field plate, and an isolation region of the first field plate is wrapped by dielectric.

2. The nitride-based semiconductor device of claim 1, wherein an outer surface of the first field plate is composed of the connection region and the isolation region.

3. The nitride-based semiconductor device of claim 1, wherein the connection region is smaller than the isolation region.

4. The nitride-based semiconductor device of claim 1, further comprising a contact via disposed over the second field plate and extending vertically to make contact with the second field plate.

5. The nitride-based semiconductor device of claim 4, wherein the contact via is directly connected to the portion of the second field plate.

6. The nitride-based semiconductor device of claim 1, further comprising:
a plurality of contact vias disposed over the second field plate and extending vertically to make contact with the second field plate, wherein all of the contact vias are arranged along a direction to form an array.

7. The nitride-based semiconductor device of claim 6, wherein all of the contact vias are directly connected to the portion of the second field plate.

8. The nitride-based semiconductor device of claim 1, wherein the second field plate has a plurality of the portions extending downward to make contact with the connection regions of the first field plate, and the connection regions of the first field plate are arranged along a direction.

9. The nitride-based semiconductor device of claim 8, wherein the connection regions are arranged to have a fixed spacing between any two of adjacent connection regions.

10. The nitride-based semiconductor device of claim 1, further comprising a dielectric layer disposed between the first and second field plates and enclosing the portion of the second field plate.

11. The nitride-based semiconductor device of claim 1, further comprising:
a third field plate disposed between the first and second field plates, wherein the third field plate has at least one portion extending downward to make contact with the first field plate.

12. The nitride-based semiconductor device of claim 11, wherein the third field plate is closest to the ohmic electrode among the first field plate, the second field plate, and the third field plate.

13. The nitride-based semiconductor device of claim 1, further comprising:
a third field plate disposed over the first and second field plates, wherein the third field plate has at least one portion extending downward to make contact with the second field plate.

14. The nitride-based semiconductor device of claim 1, wherein the second field plate comprises a recessed portion directly above the connection region of the first field plate.

15. The nitride-based semiconductor device of any one of claim 1, wherein the first field plate is parallel with the second field plate.

16. A method for manufacturing a nitride-based semiconductor device, comprising:
forming a first nitride-based semiconductor layer;
forming a second nitride-based semiconductor layer on the first nitride-based semiconductor layer;
forming a gate electrode over the second nitride-based semiconductor layer;
forming an ohmic electrode over the second nitride-based semiconductor layer;
forming a first field plate above the second nitride-based semiconductor layer and between the gate electrode and the ohmic electrode; and
forming a second field plate above the first field plate and vertically overlapping with the first field plate, wherein the second field plate has at least one portion extending downward to make contact with at least one connection region of the first field plate.

17. The method of claim 16, further comprising: wherein forming a dielectric layer to wrap an isolation region of the first field plate; and/or
forming a contact via in contact with the second field plate such that the contact via is electrically couple with the first field plate via the second field plate.

18. The method of claim 16, wherein an outer surface of the first field plate is composed of the connection region and an isolation region.

19. The method of claim 17, wherein the connection region is smaller than the isolation region.

20. (canceled)

21. A nitride-based semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer;
a gate electrode disposed above the second nitride-based semiconductor layer;
an ohmic electrode disposed above the second nitride-based semiconductor layer;
a first field plate disposed above the second nitride-based semiconductor layer and between the gate electrode and the ohmic electrode, wherein the first field plate is composed of a connection region and an isolation region; and
a second field plate disposed above the first field plate and having at least one portion extending downward to make contact with the connection region of the first field plate.

22-25. (canceled)
